(19) United States
(12) Patent Application Publication
(10) Pub. No.: US 2017/0069683 A1
(43) Pub. Date: Mar. 9, 2017

(54) MAGNETORESISTIVE MEMORY DEVICE AND MANUFACTURING METHOD OF THE SAME

(71) Applicant: KABUSHIKI KAISHA TOSHIBA, Tokyo (JP)

(72) Inventor: Kuniaki SUGIURA, Seoul (KR)

(73) Assignee: KABUSHIKI KAISHA TOSHIBA, Tokyo (JP)

(21) Appl. No.: 15/065,836

(22) Filed: Mar. 9, 2016

Related U.S. Application Data
(60) Provisional application No. 62/215,731, filed on Sep. 8, 2015.

(51) Int. Cl. H01L 27/22; H01L 43/02; H01L 43/12; H01L 43/08

(52) U.S. Cl. CPC H01L 27/222; H01L 43/08; H01L 43/02; H01L 43/12

(57) ABSTRACT

According to one embodiment, a magnetoresistive memory device includes a magnetoresistive element having a stacked layer structure includes a first magnetic layer, a second magnetic layer, and a nonmagnetic layer between the first magnetic layer and the second magnetic layer, an insulating layer provided on the first magnetic layer, a conductive layer provided on a surface of the insulating laver, opposite to the first magnetic layer, and a sidewall conductive film configure to connect the conductive layer and the first magnetic layer.

### CROSS-REFERENCE TO RELATED APPLICATIONS

This application claims the benefit of U.S. Provisional Application No. 62/215,731, filed Sep. 8, 2015, the entire contents of which are incorporated herein by reference.

### FIELD

Embodiments described herein relate generally to a magnetoresistive memory device and the manufacturing method of the same.

### BACKGROUND

Recently, a high-capacity magnetoresistive random access memory (MRAM) using a magnetic tunnel junction (MTJ) element has been drawing attention and raising expectations. The MTJ element has two magnetic layers which sandwich a tunnel barrier layer. One of the magnetic layers is a magnetization fixed layer (reference layer) in which the direction of magnetization is fixed such that the direction is not changed. The other one is a magnetization free layer (storage layer) in which the direction of magnetization can be easily inverted.

In some cases, to improve the magnetic characteristics of the MTJ element, a buffer layer and an underlayer are formed on a lower electrode before forming the MTJ element.

### BRIEF DESCRIPTION OF THE DRAWINGS

FIG. 1 is a cross-sectional view showing an element structure of a magnetoresistive memory device according to a first embodiment.

FIG. 2 is a cross-sectional view showing a modification example of the magnetoresistive memory device of the first embodiment.

FIG. 3 is a cross-sectional view showing another modification example of the magnetoresistive memory device of the first embodiment.

FIG. 4 is a cross-sectional view showing another modification example of the magnetoresistive memory device of the first embodiment.

FIGS. 5A to 5E are cross-sectional views showing steps for manufacturing the magnetoresistive memory device shown in FIG. 1.

FIGS. 6A and 6B are cross-sectional views showing steps for manufacturing the magnetoresistive memory device shown in FIG. 2.

FIG. 7 is a cross-sectional view showing an element structure of a magnetoresistive memory device according to a second embodiment.

FIGS. 8A and 8B are cross-sectional views showing steps for manufacturing the magnetoresistive memory device shown in FIG. 7.

FIG. 9 is a cross-sectional view showing an element structure of a magnetoresistive memory device according to a third embodiment.

FIGS. 10A to 10C show cross-sectional views showing steps for manufacturing the magnetoresistive memory device shown in FIG. 9.

FIG. 11 is a cross-sectional view showing an element structure of a magnetoresistive memory device according to a fourth embodiment.

FIG. 12 is a circuit structural diagram showing a memory cell array of an MRAM according to a fifth embodiment.

FIG. 13 is a cross-sectional view showing a structure of a memory cell portion of the MRAM shown in FIG. 12.

### DETAILED DESCRIPTION

In general, according to one embodiment, a magnetoresistive memory device comprises: a magnetoresistive element having a stacked layer structure includes a first magnetic layer, a second magnetic layer, and a nonmagnetic layer between the first magnetic layer and the second magnetic layer; an insulating layer provided on the first magnetic layer; a conductive layer provided on a surface of the insulating layer, opposite to the first magnetic layer; and a sidewall conductive film configure to connect. the conductive layer and the first magnetic layer.

Hereinafter, a magnetoresistive memory device is explained over various embodiments with reference to the accompanying drawings.

### First Embodiment

FIG. 1 is a cross-sectional view showing an element structure of a magnetoresistive memory device according to a first embodiment.

A buffer layer (buffer) 11 is formed on a lower electrode (not shown). On the buffer layer 11, an insulating underlayer (UL) 12 is formed. The underlayer 12 functions as a crystallization acceleration layer.

The buffer layer (a first conductive layer) 11 should be formed of a material which has a relatively high conductivity, such as Al, Be, Mg, Ca, Sr, Ba, Sc, Y, La, Zr, Hf, Ta, W, Pt or Pd. The buffer layer 11 may be a compound of, for example, HfB, MgAlB, HfAlB, ScAlB, ScHfB, HfMgB, CoPt or CoPd. The buffer layer 11 may be the lamination of these materials. With use of a metal having a high melting point and a boride thereof, the diffusion of the material of the buffer layer to the magnetic layer can be suppressed, thereby making it possible to prevent the deterioration of the MR ratio. Here, metals having a high melting point are those having a melting point higher than those of Fe and Co, which are, for example, Zr, Hf, H, Cr, Mo, Nb, Ti, Ta, and V.

The underlayer (insulating layer) 12 accelerates crystallization by uniforming the crystal plane orientation of the lavers formed above the underlayer 12. A material having a small mass can be used for the underlayer 12. For example, MgO or a nitrogen compound such as AlN, MgN, ZrN, NbN, SiN, HfN, TaN, WN, CrN, MoN, TiN, VN or AlTiN may be used.

The nitrogen compound and the oxygen compound control the dumping constant rise of the magnetic layer to touch them, and the effect of the writing current reduction is obtained. Further, the diffusion of the underlayer material to the magnetic layer can be controlled by the refractory metal's using the nitrogen compound or the oxygen compound, and, as a result, the MR ratio can be prevented being degraded. The melting point of the refractory metal is higher than that of Fe and Co. For instance, the refractory metal is Zr, Hf, W, Cr, Mo, Nb, Ti, Ta or V.

On the underlayer 12, a storage layer (SL [first magnetic layer]) 21 is formed. The width of the lower part of the storage layer 21 is the same as that of the underlayer 12 and the buffer layer 11. However, the upper part of the storage layer 21 is narrow since the storage layer 21 is partially etched. On the narrow portion of the storage layer 21, a tunnel barrier layer (nonmagnetic layer) 22 and a reference layer (RL [second magnetic layer]) 23 are formed. Thus, the tunnel barrier layer 22 is interposed between the storage layer 21 and the reference layer 23. This structure forms an MTJ element 20.

The storage layer 21 has a perpendicular magnetic anisotropy on the film surface, is variable in the direction of magnetization and is formed of, for example, CoFeB. The tunnel barrier layer 22 is provided to supply tunnel current and is formed of, for example, MgO. The reference layer 23 has a perpendicular magnetic anisotropy on the film surface, has a fixed direction of magnetization and is formed of, for example, CoFeB. The magnetic layers for the storage layer 21 and the reference layer 23 are not limited to CoFeB and only have to contain Co and Fe. Further, the materials are not limited to Co and Fe. Other ferromagnetic materials may be used. Moreover, it is also possible to use the ferromagnetic materials such as CoPt, CoNi, and CoPd as the reference layer 23.

On the reference layer 23 of the MTJ element 20, a shift cancellation layer (SCL [third magnetic layer]) 24 is formed. For the shift cancellation layer, CoPt, CoNi, or CoPd can be used. On the shift cancellation layer 24, a cap layer (cap) 25 is formed. The shift cancellation layer 24 is provided to eliminate or reduce the influence caused by the stray magnetic field from the reference layer 23, and has a magnetic anisotropy in a direction opposite to that of the reference layer 23. For the shift cancellation layer 24, the same ferromagnetic material as the reference layer 23, or an artificial lattice in which Co and Pt are alternately stacked may be used. The cap layer 25 should be formed of a conductive metal material. For example, Pt, W, Ta or Ru may be used.

A sidewall insulating film 31 is formed so as to cover the sidewalls of the shift cancellation layer 24, the reference layer 23, the tunnel barrier layer 22 and the partly narrow portion of the storage layer 21. The sidewall insulating film 31 is provided to protect the sidewall of the MTJ element 20, and is, for example, a silicon. dioxide (SiO₂) film or a silicon nitride (SiN) film.

Further, a sidewall conductive film 32 is formed so as to cover the sidewalls of the buffer layer 11, the underlayer 12 and the storage layer 21, and a part of the sidewall insulating film 31. The sidewall conductive film 32 is formed of the etching product of the buffer layer 11 and contains the same material as the buffer layer 11. When the buffer layer 11 is formed of noble metal, the sidewall conductive layer 32 is also formed of noble metal. By forming the sidewall conductive layer 32, the storage layer 21 is electrically connected to the buffer layer 11.

Thus, in the present embodiment, the sidewall of the buffer layer 11 is electrically connected to the sidewall of the storage layer 21 via the sidewall conductive film 32. Thus, current can be supplied without the intervention of the underlayer 12 having a high resistance. In this manner, even if a material having a thick film is used for the underlayer 12, the increase in the series resistance can be prevented.

It is possible to reduce the series resistance of the entire element while the write current Ic is reduced and the thermal stability ΔE is increased by using the underlayer 12. Thus, it is possible to realize a magnetoresistive memory device which has excellent element characteristics.

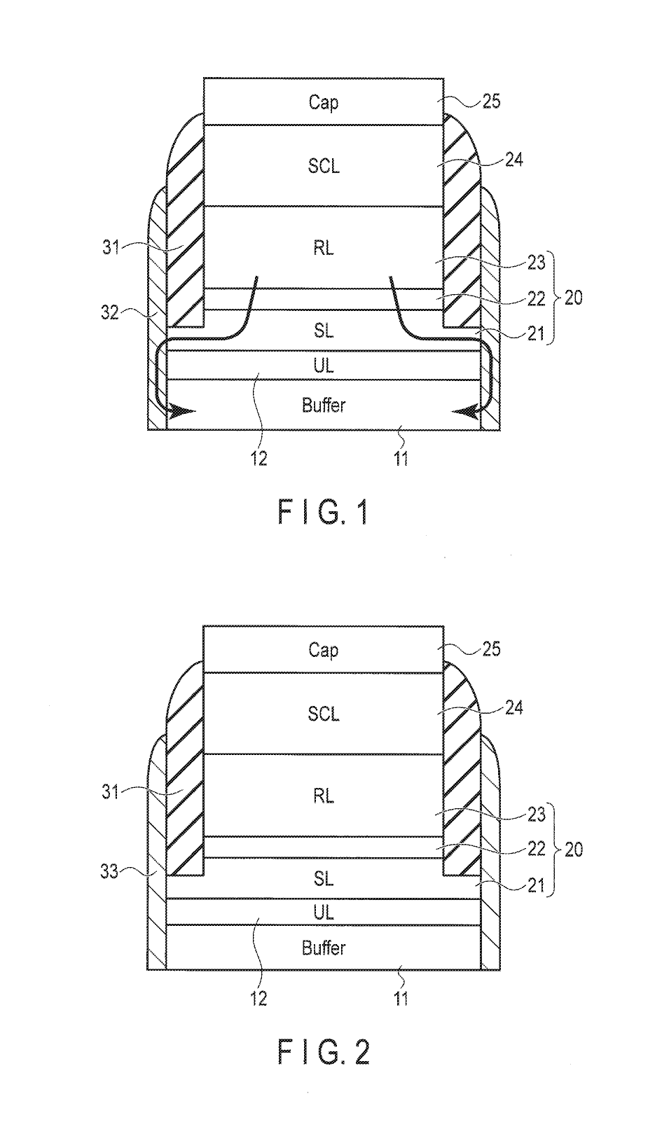

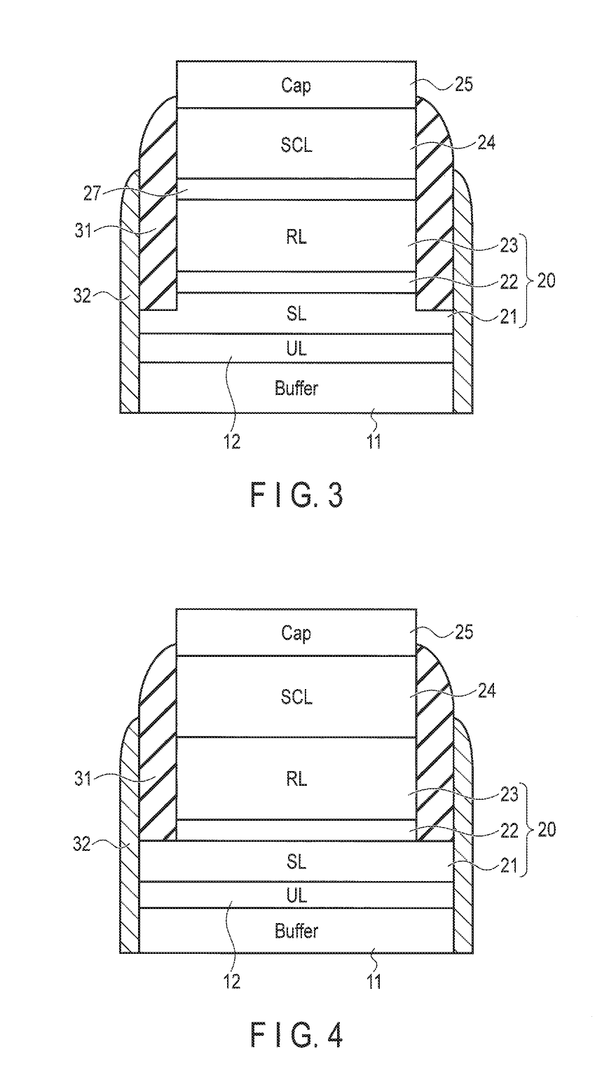

The sidewall conductive film 32 is not necessarily formed of the same material as the buffer layer 11. For example, as shown in FIG. 2, a sidewall conductive film 33 in which metal materials such as W, TiN and Ta are stacked by an MOCVD method, etc., may be provided so as to cover the sidewalls of the buffer layer 11, the underlayer 12 and the storage layer 21. Moreover, as shown in FIG. 3, a nonmagnetic layer 27 may be inserted between the reference layer 23 and the shift cancellation layer 24.

In FIG. 1, a step is formed by etching the upper part of the storage layer 21 so as to have the same width as the tunnel barrier layer 22. However, a step is not necessarily formed. For example, as shown in FIG. 4, the entire storage layer 21 may be formed so as to be wider than the upper layers. In this case, the sidewall insulating film 31 is not formed on the sidewall of the storage layer 21 and is formed on only the sidewalls of the tunnel barrier layer 22, the reference layer 23 and the shift cancellation layer 24. The sidewall conductive film 32 is formed on the entire sidewall of the storage layer 21 as well as the sidewalls of the buffer layer 11 and the underlayer 12.

In addition to the storage layer 21, the tunnel barrier layer 22 may be formed so as to have the same width as the underlayer 12 and the buffer layer 11. In this case, the sidewall insulating film 31 is not formed. on the sidewall of the tunnel barrier layer 22 and is formed on only the sidewalls of the reference layer 23 and the shift cancellation layer 24. The sidewall conductive film 32 is formed on the sidewalls of the buffer layer 11, the underlayer 12, the storage layer 21 and the tunnel barrier layer 22.

Even if the sidewall conductive film 32 is in contact with the sidewall of the tunnel barrier layer 22, current can be perpendicularly supplied to the tunnel barrier layer 22 since the resistance of the storage layer 21 is significantly lower than that of the tunnel barrier layer 22. In other words, in a structure in which the sidewall conductive film 32 is not in contact with the reference layer 23, current can be supplied to the tunnel barrier layer 22. By this structure, the MTJ operation can be maintained.

Here, the use of an underlayer (underlying insulating layer) having a low atomic mass for the base of a storage layer (SL) of an MTJ element is effective in reducing the write current Ic and increasing the thermal stability ΔE. However, in this type of underlayer, the resistance is high. Therefore, when the MTJ element is formed, the series resistance of the entire element becomes high.

On the other hand, in this embodiment, the series resistance of the entire element can be lowered by the arrangement of a metallic conductive path to the sidewall of the underlayer.

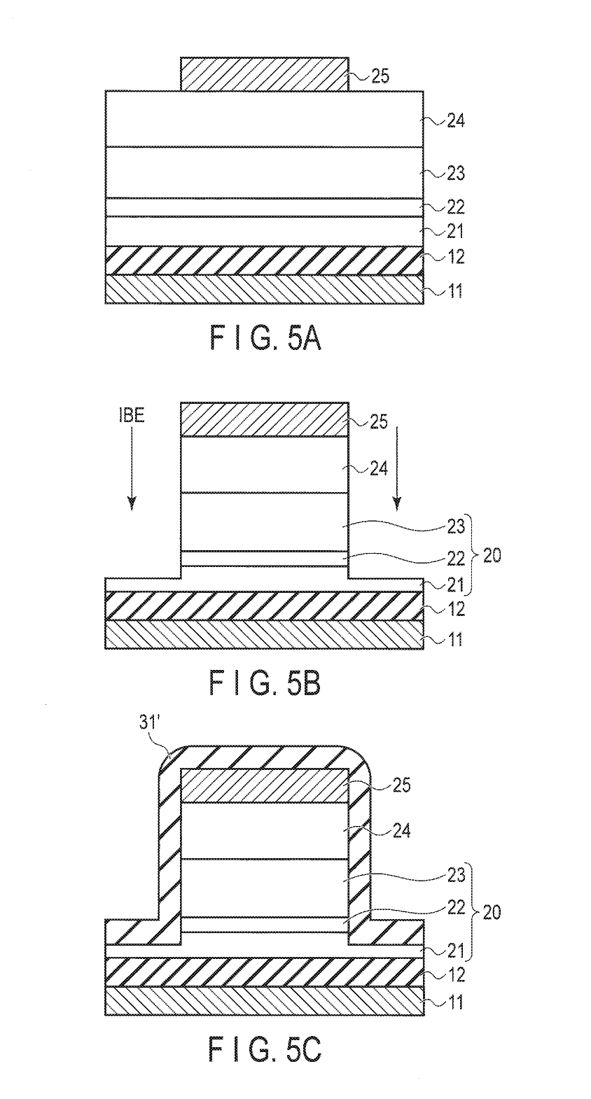

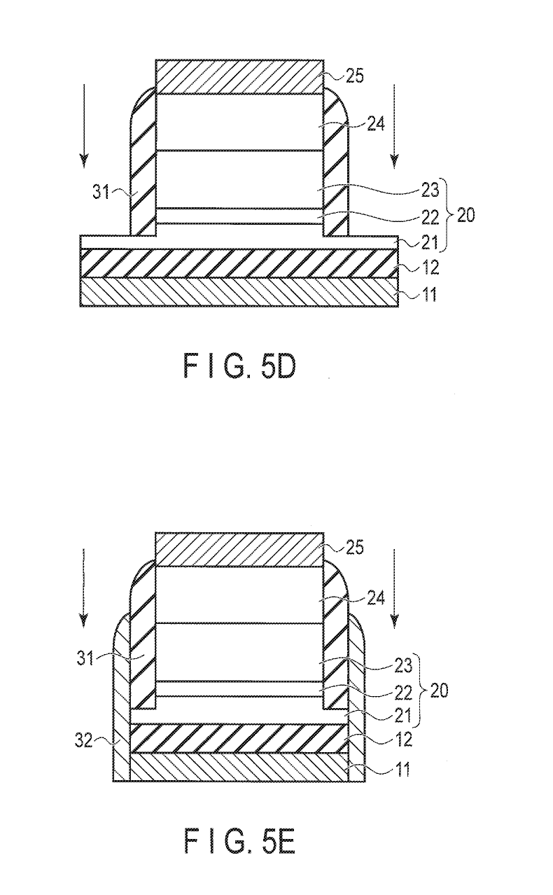

Now, this specification explains a method for manufacturing the magnetoresistive memory device of the present embodiment with reference to FIGS. 5A to 5E.

As shown in FIG. 5A, the buffer layer 11 having a good conductivity, the insulating underlayer 12, the storage layer 21 of CoFeB, the tunnel barrier layer 22 of MgO, the reference layer 23 of CoFeB, the shift cancellation layer 24 of CoPt and the cap layer (mask material layer) 25 of Ta are stacked on a substrate (not shown) in which the lower electrode is buried. Subsequently, the cap layer 25 is processed into an MTJ-element pattern.

Subsequently, as shown in FIG. 5B, the MTJ element 20 is formed by performing selective etching with the cap layer 25 used as a mask through an ion beam etching (IBE) method, etc. In this etching method, an etching process is applied to the upper surface of the shift cancellation layer 24 to the middle portion of the storage layer 21. The etching method is not limited to an IBE method. A reactive ion etching (RIE) method may be employed.

Subsequently, as shown in FIG. 5C, an insulating film 31′ of SiN, etc, is accumulated through a CVD method so as to cover the MTJ element 20, the shift cancellation layer 24 and the cap layer 25.

Subsequently, as shown in FIG. 5C, the sidewall insulating film 31 is formed by etching the insulating film 31′ through a low-angle IBE method or an RIE method. In other words, through the etch back of the insulating film 31′, the sidewall insulating film 31 is formed so as to cover the sidewalls of the shift cancellation layer 24, the reference layer 23, the tunnel barrier layer 22 and the upper part of the storage layer 21.

Subsequently, as shown in FIG. 5E, the storage layer 21, the underlayer 12 and the buffer layer 11 are selectively etched through a low-angle IBE, using the sidewall insulating film 31 and the cap layer 25 as masks. At this time, the etching product of the buffer layer 11 is accumulated on the sidewalls of the storage layer 21, the underlayer 12 and the buffer layer 11. In this manner, the sidewall conductive film 32 is formed. The sidewall conductive film 32 is formed so as to cover the sidewall insulating film 31. There is no problem if the sidewall conductive film 32 is not in contact with the shift cancellation layer 24 or the cap layer 25. In other words, the top portion of the sidewall conductive film 32 must be lower than the top portion of the sidewall insulating film 31.

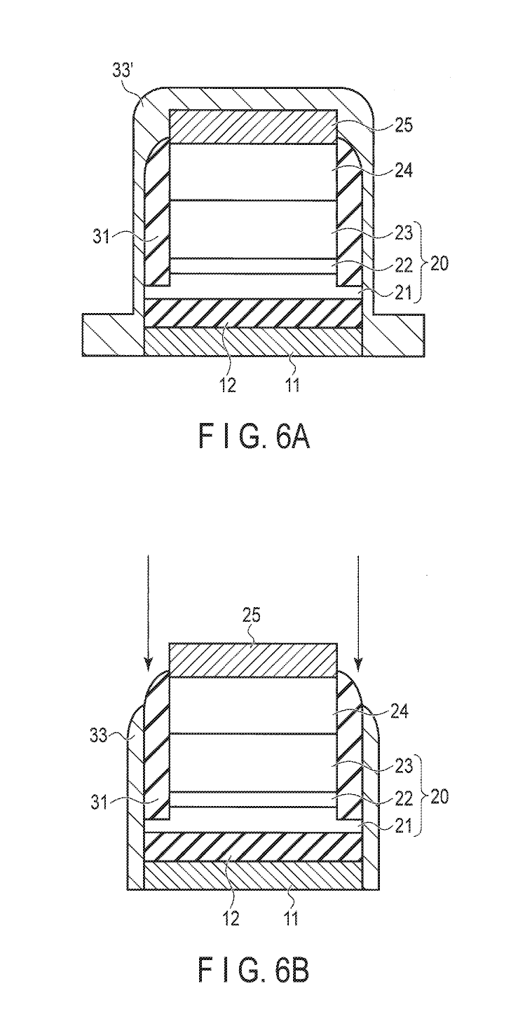

When the redeposition of the etching product of the buffer layer 11 is insufficient for the film thickness of the sidewall conductive film 32, the sidewall conductive film may be formed intentionally. Specifically, after the etching shown in FIG. 5E, a conductive film 33′ of W, TiN, Ta, etc. , is accumulated by an MOCVD method or a sputtering method as shown in FIG. 6A. Subsequently, as shown in FIG. 6B, an etching process is applied to the whole surface through a low-angle IBE method or an RIE method. In this manner, the conductive film 33 is left on the sidewalls of the storage layer 21, the underlayer 12 and the buffer layer 11. At this time, an etching process is applied until the top portion of the conductive film 33 is lower than the top portion of the sidewall insulating film 31. Thus, the sidewall conductive film 33 having the same structure as FIG. 2 is formed.

The shape of the sidewall conductive film 33 shown in FIG. 6B is different from that in FIG. 2. The shape differs depending on the etching conditions of the IBE method or the RIE method. Any shape may be accepted as long as the sidewall conductive film 33 is in contact with the sidewalls of the buffer layer 11 and the storage layer 21 without being in contact with the shift cancellation layer 24 and the cap layer 25.

### Second Embodiment

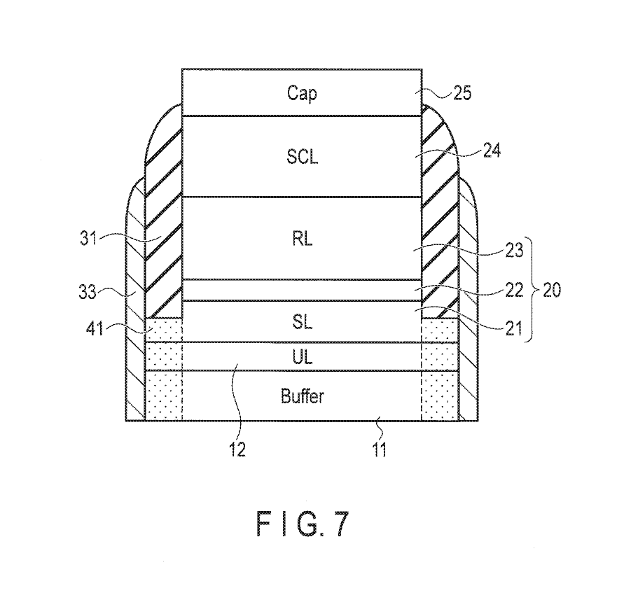

FIG. 7 is a cross-sectional view showing an element structure of a magnetoresistive memory device according to a second embodiment. The elements identical with those of FIG. 1 are denoted by the same reference numbers. Thus, the detailed explanation of the elements is omitted.

The present embodiment is different from the first embodiment in respect that the extension portion (the step portion) of a storage layer 21 is nonmagnetic. Specifically, an end portion 41 of the storage layer 21 of an MTJ element 20 is extended outward from the end portions of a tunnel barrier layer 22 and a reference layer 23. This extension portion is made nonmagnetic by ion injection, etc. Thus, the substantive MTJ element 20 has approximately the same width from the storage layer 21 to the reference layer 23.

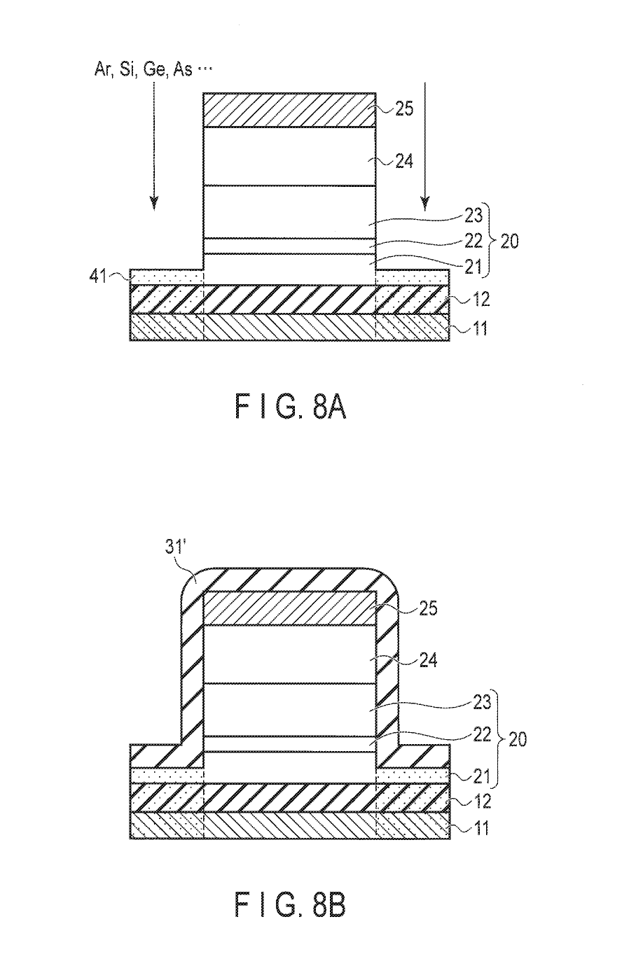

The basic manufacturing procedure of the present embodiment is the same as that of the first embodiment. In the present embodiment, after the etching process shown in FIG. 5B, ion injection is applied using one of Ar, Si, Ge, As, etc., as shown in FIG. 8A. In this manner, the end portion of the storage layer 21 is made nonmagnetic. At this time, ion injection is applied to an underlayer 12 and a buffer layer 11 in addition to the storage layer 21. This application does not cause any problem.

Subsequently, as shown in FIG. 8B, an insulating film 31′ of SiN, etc, is accumulated through a CVD method so as to cover the MTJ element 20, a shift cancellation layer 24 and a cap layer 25.

Subsequently, in a manner similar to the process shown in FIG. 6B, a sidewall insulating film 31 is formed by etching the whole surface through a low-angle IBE method or an RIE method. In a manner similar to that of the first embodiment, a sidewall conductive film 33 is formed. Thus, the structure shown in FIG. 7 is completed.

In the present embodiment, similarly, the sidewall insulating film 31 is formed on the sidewall of the MTJ element 20. Further, the sidewall conductive film 33 is formed on the sidewalls of the buffer layer 11, the underlayer 12 and the storage layer 21. This structure enables current to be supplied without passing through the underlayer 12 having a high resistance. Thus, an effect similar to that of the first embodiment can be obtained.

In addition to the above, in the present embodiment, the extension portion of the storage layer 21 is nonmagnetic. The following effects can be obtained from this structure. In the structure of the first embodiment, the magnetic characteristics may be deteriorated by the extension portion of the storage layer 21. This problem can be solved by structuring the extension portion of the storage layer 21 so as to be nonmagnetic as shown in the present embodiment. In addition, the present embodiment is advantageous in respect that the width of the substantive storage layer 21 can be approximately the same as that of the tunnel layer 22 and the reference layer 23.

### Third Embodiment

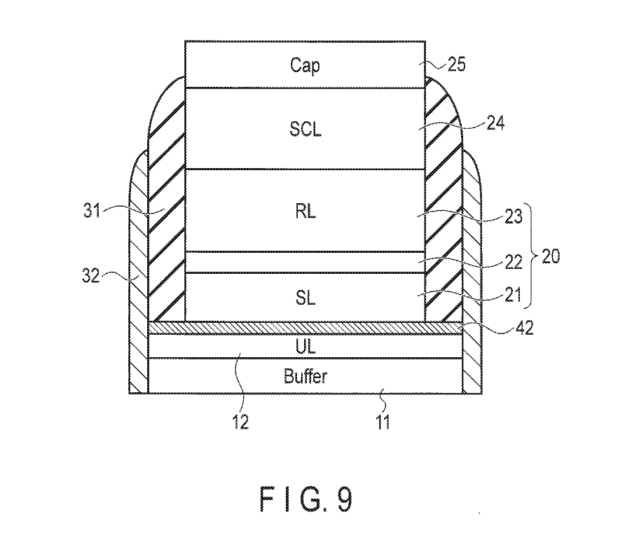

FIG. 9 is a cross-sectional view showing an element structure of a magnetoresistive memory device according to a third embodiment. The elements identical with those of FIG. 1 are denoted by the same reference numbers. Thus, the detailed explanation of the elements is omitted.

The present embodiment is different from the first embodiment in respect that a metal conductive layer (a second conductive layer) 42 is interposed between an underlayer (insulating layer) 12 and a storage layer 21. The metal conductive layer 42 of Ta, W, Ti, TiN, TaN, etc., is formed on the underlayer 12. A buffer layer (a first conductive layer) 11, the underlayer 12 and the metal conductive layer 42 have the same width.

The storage layer 21, a tunnel barrier layer 22, a reference layer 23, a shift cancellation layer 24 and a cap layer 25 are accumulated on the metal conductive layer 42. The width is constant from the storage layer 21 to the cap layer 25. Each of the layers 21 to 25 is narrower than the metal conductive layer 42.

A sidewall insulating film 31 is formed so as to cover the sidewalls of the shift cancellation layer 24, the reference layer 23, the tunnel barrier layer 22 and the storage layer 21. Further, a sidewall conductive film 32 is formed so as to cover the sidewalls of the buffer layer 11, the underlayer 12 and the metal conductive layer 42 and a part of the sidewall insulating film 31.

The sidewall conductive film 32 is formed of the etching product of the buffer layer 11 and is formed of the same material as the buffer layer 11. By forming the sidewall conductive film 32, the storage layer 21 is electrically connected to the buffer layer 11.

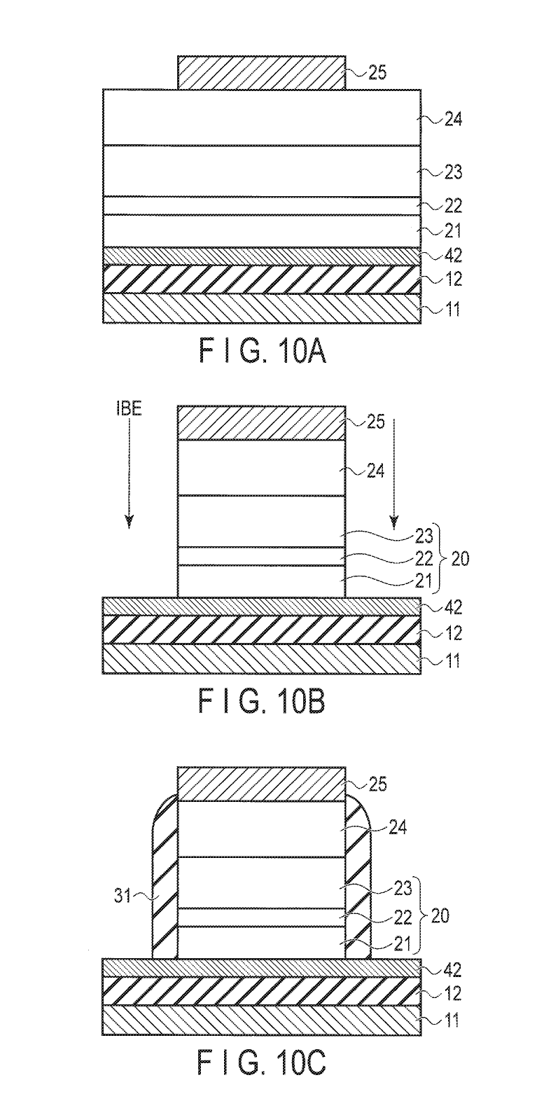

To manufacture the structure of the present embodiment, as shown in FIG. 10A, the buffer layer (first conductive layer) 11, the underlayer (insulating layer) 12, the metal conductive layer (second conductive layer) 42, the storage layer 21, the tunnel barrier layer 22, the reference layer 23, the shift cancellation layer 24 and the cap layer 25 are stacked on a substrate (not shown) in which a lower electrode is buried. Subsequently, the cap layer (mask material layer) 25 is processed into an MTJ-element pattern.

Subsequently, as shown in FIG. 10B, an MTJ element 20 is formed by applying selective etching to the shift cancellation layer 24 to the storage layer 21 with the cap layer 25 used as a mask through an IBE method, etc. In this etching, it is easy to stop the etching process in the metal conductive layer 42.

Subsequently, in a manner similar to that of the first embodiment, as shown in FIG. 10C, the sidewall insulating film 31 is formed so as to cover the sidewalls of the storage layer 21, the tunnel barrier layer 22, the reference layer 23 and the shift cancellation layer 24.

Subsequently, the metal conductive layer 42, the underlayer 12 and the buffer layer 11 are selectively etched, using the sidewall insulating film 31 and the cap layer 25 as masks. In addition, the sidewall conductive film 32 is formed so as to cover the sidewalls of the buffer layer 11, the underlayer 12 and the metal conductive layer 42, and a part of the sidewall insulating film 32. Thus, the structure shown in FIG. 9 is completed.

In place of the sidewall conductive film 32 of the etching product of the buffer layer 11, as shown in FIG. 2, FIG. 6A and FIG. 6B, a sidewall conductive film 33 may be formed by accumulation and etch back of a metal film.

As described above, in the present embodiment, the metal conductive layer 42 is formed under the storage layer 21 of the MTJ element 20. The sidewall insulating film 31 is formed on the sidewall of the MTJ element 20. In addition, the sidewall conductive film 32 is formed on the sidewalls of the buffer layer 11, the underlayer 12 and the metal conductive layer 42. This structure enables current to be supplied without passing through the underlayer 12 having a high resistance. Thus, an effect similar to that of the first embodiment can be obtained.

In addition, even when the contact area with the sidewall conductive film 32 is small, current can be sufficiently supplied without passing through the underlayer 12 by using a material having a high conductivity for the metal conductive layer 42. Thus, it is possible to considerably reduce the series resistance.

### Fourth Embodiment

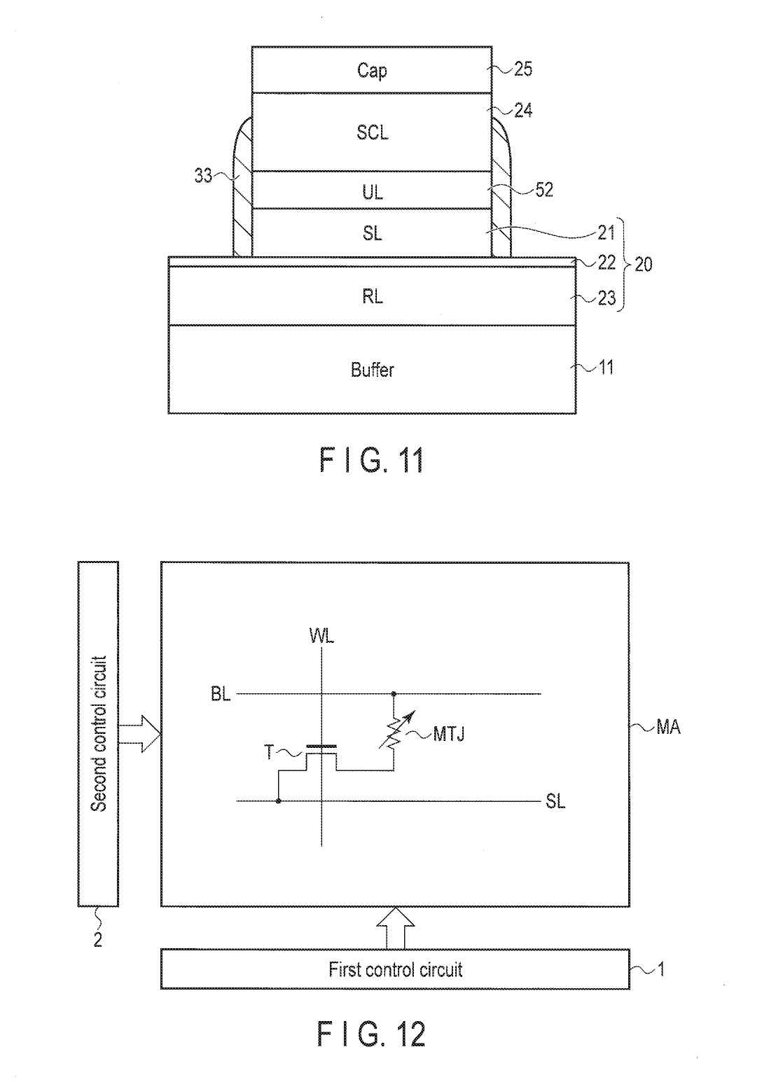

FIG. 11 is a cross-sectional view showing an element structure of a magnetoresistive memory device according to a fourth embodiment. The elements identical with those of FIG. 1 are denoted by the same reference numbers. Thus, the detailed explanation of the elements is omitted.

The present embodiment is different from the first embodiment in respect that the longitudinal relationship between a storage layer 21 and a reference layer 23 is reversed.

The reference layer 23 and a tunnel barrier layer 22 are formed on a buffer layer 11. These lavers 11, 23 and 22 have the same width.

The storage layer 21, a crystallization acceleration layer (insulating layer) 52, a shift cancellation layer 24 and a cap layer 25 are formed on the tunnel barrier layer 22. These layers 21, 52, 24 and 25 have the same width and are narrower than the tunnel barrier layer 22.

A sidewall conductive film 33 is formed so as to cover the sidewalls of the shift cancellation layer 24, the crystallization acceleration layer 52 and the storage layer 21. In a manner similar to that of the first embodiment, the sidewall conductive film 33 may be formed by accumulation and etch back of a metal film.

Thus, in the present embodiment, the shift cancellation layer 24 and the storage layer 21 are electrically connected to each other via the sidewall conductive film 33 in an MTJ element 20 in which the storage layer 21 is provided on the upper side. Thus, current can be supplied without passing through a crystallization acceleration layer 52 having a high resistance. In this manner, an effect similar to that of the first embodiment can be obtained.

### Fifth Embodiment

FIG. 12 is a circuit structural diagram showing a memory cell array of an MRAM according to a fifth embodiment. In this embodiment, the magnetoresistive memory device of the first embodiment explained above is used as each memory cell of the memory cell array.

The memory cell of the memory cell array MA comprises a serial connector for an MTJ element as a magnetic memory element and a switch element (for example, a field-effect transistor [FET]) T. An end of the serial connector (in other words, an end of the MTJ element) is electrically connected to a bit line BL. The other end of the serial connector (in other words, an end of the switch element T) is electrically connected to a source line SL.

The control terminal of the switch element T, for example, the gate electrode of the FET is electrically connected to a word line WL. The potential of the word line WL is controlled by a first control circuit 1. The potential of the bit line EL and the source line SL is controlled by a second control circuit 2.

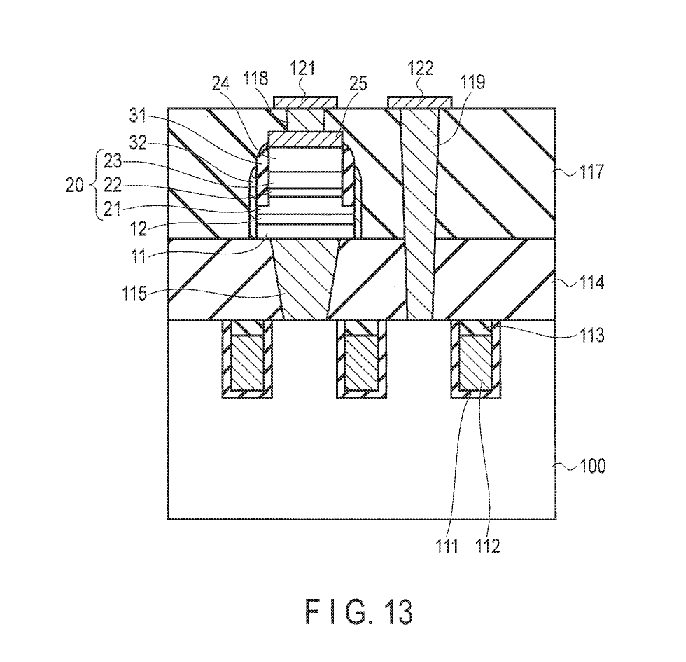

FIG. 13 is a cross-sectional view showing the structure of the memory cell portion using the magnetic memory element according to the present embodiment.

A MOS transistor for switching is formed in the surface portion of an Si substrate 100. An interlayer insulating film 114 of SiO₂, etc., is formed on the MOS transistor. The transistor has a buried-gate structure in which a gate electrode 112 is buried in a groove provided in the substrate 100 via a gate insulating film 111. The gate electrode 112 is buried up to the middle portion of the groove. On the gate electrode 112, a protective insulating film 113 of SiN, etc., is formed. A source/drain area (not shown) is formed by diffusing p-type or n-type impurities to the substrate 100 on both sides of the buried-gate structure.

The structure of the transistor portion is not limited to a buried-gate structure. For example, a gate electrode may be formed on the surface of the Si substrate 100 via a gate insulating film. The structure of the transistor portion may be any structure as long as the structure functions as a switching element.

A contact hole for connection to the drain of the transistor is formed in the interlayer insulating film 114. A lower electrode (BEC) 115 is buried in the contact hole. The lower electrode 115 is formed of, for example, Ta, W, TiN, or TaN.

For example, the above structure can be manufactured in the following manner. First, the MOS transistor for switching (not shown) having a buried-gate structure is formed in the surface portion of the Si substrate 100. Subsequently, the interlayer insulating film 114 of SiO₂, etc., is accumulated on the Si substrate 100 through a CVD method. Subsequently, the contact hole for connection to the drain of the transistor is formed in the interlayer insulating film 114. Subsequently, the lower electrode (BEC) 115 of crystalline Ta is buried in the contact hole. More specifically, a Ta film is accumulated on the interlayer insulating film 114 through a sputtering method, etc., so as to fill the contact hole. Subsequently, the Ta film on the interlayer insulating film is removed through chemical mechanical etching (CMP). Thus, the Ta film remains only in the contact hole.

In a manner similar to that of the first embodiment, a buffer layer 11, an underlayer 12, an MTJ element 20, a shift cancellation layer 24 and a cap layer 25 are formed on the lower electrode 115. In a manner similar to that of the first embodiment, a sidewall insulating film 31 is formed so as to cover the sidewalls of the shift cancellation layer 24, a reference layer 23, a tunnel barrier layer 22 and the partly narrow portion of a storage layer 21. Further, a sidewall conductive film 32 is formed so as to cover the sidewalls of the buffer layer 11, the underlayer 12 and the storage layer 21, and a part of the sidewall insulating film 31. By forming the sidewall conductive film 32, the storage layer 21 is electrically connected to the buffer layer 11.

An interlayer insulating film 117 is formed on the interlayer insulating film 114 so as to cover the cap layer 25, the sidewall, insulating film 31 and the sidewall conductive film 32. A contact plug (upper electrode) 118 is formed so as to penetrate the interlayer insulating film 117 and reach the cap layer 25. The upper electrode 118 is formed of, for example, Ta, W, TiN, or TaN. Further, a contact plug 119 having a buried structure is formed so as to penetrate the interlayer insulating film 117 and the interlayer insulating film 114 and be connected to the source of the transistor portion. An interconnect (BL) 121 connected to the contact plug 118 and an interconnect (SL) 12 connected to the contact plug 119 are formed on the interlayer insulating film 117.

In this structure, in a manner similar to that of the first embodiment explained above, the buffer layer 11 is electrically connected to the storage layer 21 via the sidewall conductive film 32. This structure enables current to be supplied without passing through the underlayer 12 having a high resistance. Thus, an effect similar to that of the first embodiment can be obtained.

### Modification Examples

The present invention is not limited to the embodiments described above.

In the first to third embodiments, the buffer layer as a conductive layer is formed under the underlayer as an insulating layer. However, the buffer layer may not be provided. If a layer having a sufficiently good conductivity is provided under the underlayer, it is possible to realize the current path by the sidewall conductive film, in other words, a feature of the embodiments.

The materials of the sidewall conductive film are not limited to the materials explained in the above embodiments, and may be appropriately changed depending on the specification. The sidewall conductive film should have a film thickness through which a sufficient current path can be obtained.

The sidewall insulating film is not limited to a silicon oxidized film or a silicon nitride film. The material of the sidewall insulating film may be any material as long as it does not deteriorate the characteristics of the MTJ element even when the material is in contact with the MTJ element. The thickness of the sidewall insulating film should be set to an extent that the conductivity between the sidewall conductive film and the tunnel barrier layer or the reference layer can be prevented. When the sidewall conductive film is not electrically connected to the tunnel barrier layer or the reference layer, etc., even without the sidewall insulating film, the sidewall insulating film may be omitted.

If the effect by the stray magnetic field from the reference layer is less, the shift cancellation layer may be omitted. Further, the structures of the transistor for switching and the lower electrode are not limited to the above embodiments at all, and may be appropriately changed depending on the specification. While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A magnetoresistive memory device comprising:
a magnetoresistive element having a stacked layer structure includes a first magnetic layer, a second magnetic layer, and a nonmagnetic layer between the first magnetic layer and the second magnetic layer;
an insulating layer provided on the first magnetic layer;
a conductive layer provided on a surface of the insulating layer, opposite to the first magnetic layer; and
a sidewall conductive film configured to connect the conductive layer and the first magnetic layer.

2. The device of claim 1, wherein
the first magnetic layer is a storage layer which has a perpendicular magnetic anisotropy on a film surface and has a variable magnetization direction,
the nonmagnetic layer is a tunnel barrier layer in which tunnel current flows, and
the second magnetic layer is a reference layer which has a perpendicular magnetic anisotropy on a film surface and has a fixed magnetization direction.

3. The device of claim 1, further comprising
a third magnetic layer provided on a surface of the second magnetic layer, opposite to the nonmagnetic layer.

4. The device of claim 1, wherein
the sidewall conductive film is provided on sidewalls of the conductive layer, the insulating layer and the first magnetic layer.

5. The device of claim 1, further comprising
a semiconductor substrate, a transistor for switching provided on the semiconductor substrate and a lower electrode connected to the transistor,
wherein the conductive layer is provided on the lower electrode.

6. The device of claim 4, further comprising
a sidewall insulating film provided on a sidewall of the second. magnetic layer, wherein
the sidewall conductive film is provided on the sidewalls of the conductive layer, the insulating layer and the first magnetic layer, and a part of the sidewall insulating film.

7. The device of claim 6, wherein
the first magnetic layer comprises a step such that an upper part of an end portion steps back in comparison with a lower part of the end portion,
the sidewall insulating film is provided on the sidewall of the second magnetic layer, a sidewall of the nonmagnetic layer and a sidewall of the upper part of the first magnetic layer, and
the sidewall conductive film is provided on a sidewall of the lower part of the first magnetic layer.

8. The device of claim 7, wherein
the lower part of the end portion of the first magnetic layer is nonmagnetic.

9. The device of claim 1, wherein
a material of the sidewall conductive film is same as a material of the conductive layer.

10. A magnetoresistive memory device, comprising:
a first conductive layer provided on a substrate;
an insulating layer provided on the first conductive layer;
a second conductive layer provided on the insulating layer;
a magnetoresistive element provided on the second conductive layer, the magnetoresistive element having a stacked layer structure includes a first magnetic layer on the second conductive layer side, a second magnetic layer, and a nonmagnetic layer between the first magnetic layer and the second magnetic layer; and
a sidewall conductive film configured to connect the second conductive layer and the first conductive layer.

11. The device of claim 10, wherein
the first magnetic layer is a storage layer which has a perpendicular magnetic anisotropy on a film surface and has a variable magnetization direction,
the nonmagnetic layer is a tunnel barrier layer in which tunnel current flows, and
the second magnetic layer is a reference layer which has a perpendicular magnetic anisotropy on a film surface and has a fixed magnetization direction.

12. The device of claim 10, further comprising
a third magnetic layer provided on a surface of the second magnetic layer, opposite to the nonmagnetic layer.

13. The device of claim 10, further comprising
a sidewall insulating film provided on sidewalls of the first magnetic layer, the nonmagnetic layer and the second magnetic layer, wherein
the sidewall conductive film is provided on sidewalls of the first conductive layer, the insulating layer and the second conductive layer, and a part of the sidewall insulating film.

14. The device of claim 10, wherein
the magnetoresistive element is narrower than the second conductive layer, and
a sidewall of the magnetoresistive element and a sidewall of the second conductive layer comprise a step.

15. The device of claim 10, wherein
a material of the sidewall conductive film is same as a material of the first conductive layer.

16. The device of claim 10, wherein
the substrate comprises a semiconductor substrate, a transistor for switching provided on the semiconductor substrate, and a lower electrode connected to the transistor, and
the first conductive layer is provided on the lower electrode.

17. A method for manufacturing a magnetoresistive memory device, the method comprising:
forming an insulating layer on a conductive layer;
forming a stacked layer structure on the insulating layer, the stacked layer structure including a first magnetic layer on a lower side, a second magnetic layer on an upper side, and a nonmagnetic layer between the first magnetic layer and the second magnetic layer;
forming a mask material layer corresponding to a pattern of an MTJ element on the stacked layer structure;
forming a magnetoresistive element by using the mask material layer as a mask and selectively etching the stacked layer structure from the second magnetic layer side so as to reach the first magnetic layer or a middle portion of the first magnetic layer;
forming a sidewall insulating film to cover sidewalls of the second magnetic layer and the nonmagnetic layer exposed by the etching;
selectively etching the first magnetic layer, the insulating layer and the conductive layer with the mask material layer and the sidewall insulating film as masks; and
forming a sidewall conductive film to over sidewalls of the first magnetic layer, the insulating layer and the conductive layer exposed by the etching using the mask material layer and the sidewall insulating film as the masks.

18. The method of claim 17, wherein
the forming the sidewall conductive film is attaching an etching product of the conductive layer by the etching using the mask material layer and the sidewall insulating film as the masks to the sidewalls.

19. The method of claim 17, wherein
the forming the sidewall conductive film is, after a conductive film is accumulated to cover the magnetoresistive element, the insulating layer, the conductive layer and the sidewall insulating film, etching the conductive film such that a top portion of the conductive film is lower than a top portion of the sidewall insulating film.
